(19) United States
(12) Patent Application Publication
(10) Pub. No.: US 2011/0299343 A1
(43) Pub. Date: Dec. 8, 2011

(54) NON-VOLATILE MEMORY DEVICE, PRECHARGE VOLTAGE CONTROLLING METHOD THEREOF, AND SYSTEM INCLUDING THE SAME

(76) Inventor: Jin Yub LEE, Seoul (KR)

(21) Appl. No.: 13/151,346

(22) Filed: Jun. 2, 2011

(30) Foreign Application Priority Data
Jun. 3, 2010 (KR) 10-2010-0052289

(51) Int. Cl. G11C 16/06

(52) U.S. Cl. 365/185.25

(57) ABSTRACT

A non-volatile memory device, precharge voltage control method thereof, and system including the same are provided. The non-volatile memory device includes a bit line connected with a non-volatile memory cell, a precharge voltage generation circuit configured to generate a precharge voltage during a precharge operation, and a control circuit configured to apply the precharge voltage of a second level to the bit line in response to a control signal at a first level during a precharge period in a normal read operation and to apply the precharge voltage of a fourth level to the bit line in response to the control signal at the third level during a precharge period in a verify read or erase operation.

### CROSS-REFERENCE TO RELATED APPLICATIONS

This application claims priority under 35 U.S.C. §119 to Korean Patent Application No. 10-2010-0052289, filed on Jun. 3, 2010, in the Korean Intellectual Property Office, and entitled: “Non-Volatile Memory Device, Precharge Voltage Controlling Method Thereof, and System Including the Same,” which is incorporated by reference herein in its entirety.

### BACKGROUND

1. Field

Embodiments relate to a non-volatile memory device, and more particularly, to a non-volatile memory devices for increasing the program/erase endurance of a non-volatile memory cell by controlling a precharge voltage provided to a bit line connected to the non-volatile memory cell, a method of controlling the precharge voltage of the non-volatile memory device, and a system including the same.

2. Description of the Related Art

Even when not powered, non-volatile memory devices retain data stored in cells. Among non-volatile memory devices, flash memory devices are widely used in computers and memory cards since they can electrically erase data from cells all at once.

Flash memory devices are divided into NOR flash memory devices and NAND flash memory devices depending on the structure of connection between a cell and a bit line. NOR flash memory devices usually consume a relatively large amount of current and are thus disadvantageous for a high degree of integration, but they are advantageous for high speed. NAND flash memory devices are advantageous for a high degree of integration since they consume less cell current than NOR flash memory devices.

### SUMMARY

One or more embodiments may provide a memory device configured to control a precharge voltage applied to a bit line connected with a non-volatile memory cell so that program/erase endurance is increased.

One or more embodiments provide a non-volatile memory device, including a bit line connected with a non-volatile memory cell, a precharge voltage generation circuit configured to generate a precharge voltage during a precharge operation, a control circuit configured to apply the precharge voltage of a second level to the bit line in response to a control signal at a first level during a precharge period during a normal read operation and to apply the precharge voltage of a fourth level to the bit line in response to the control signal at the third level during a precharge period during a verify read operation or erase operation.

The first level may be higher than the third level and the second level is higher than the fourth level.

A control voltage generation circuit may be configured to generate the control signal.

The control voltage generation circuit may be configured to generate the control signal at a fifth level during a sensing period during the normal read operation and generate the control signal at a sixth level lower than the fifth level during a sensing period during the verify read or erase operation.

One or more embodiments may provide a memory system including a non-volatile memory device, including a bit line connected with a non-volatile memory cell, a precharge voltage generation circuit configured to generate a precharge voltage during a precharge operation, a control circuit configured to apply the precharge voltage of a second level to the bit line in response to a control signal at a first level during a precharge period during a normal read operation and to apply the precharge voltage of a fourth level to the bit line in response to the control signal at the third level during a precharge period during a verify read operation or erase operation, and a memory controller configured to control the non-volatile memory device.

The first level may be higher than the third level and the second level is higher than the fourth level.

The non-volatile memory device may further include a control voltage generation circuit configured to generate the control signal.

The control voltage generation circuit may be configured to generate the control signal at a fifth level during a sensing period during the normal read operation and generate the control signal at a sixth level lower than the fifth level during a sensing period during the verify read or erase operation.

One or more embodiments may provide a method of controlling a precharge voltage in a non-volatile memory device, the method including applying the precharge voltage of a second level to a bit line in response to a control signal at a first level during a precharge period during a normal read operation, and applying the precharge voltage of a fourth level to the bit line in response to the control signal at a third level during a precharge period during a verify read or erase operation.

The first level may be higher than the third level and the second level is higher than the fourth level.

The method may further include generating the control signal at a fifth level during a sensing period during the normal read operation, and generating the control signal at a sixth level lower than the fifth level during a sensing period during the verify read or erase operation.

One or more embodiments may provide a non-volatile memory device including a plurality of non-volatile memory cells, the device including a bit line connected to at least one the plurality of non-volatile memory cells configured to be controlled during a normal read operation and a verify read or erase operation, each of the normal read operation and the verify read or erase operation including a plurality of periods, a control circuit configured to apply a plurality of voltages having different magnitudes to the bit line, wherein at least one of the plurality of voltages applied during one of the plurality of periods of the normal read operation is higher than another of the plurality of voltages applied during a same respective one of the plurality of periods of the verify read or erase operation.

The plurality of periods may include a precharge period and the respective one of the plurality of voltages applied during a precharge period of the normal read operation is higher than a respective other one of the plurality of voltages applied during a precharge period of the verify read or erase operation.

The plurality of periods may include a sensing period and the respective one of the plurality of voltages applied during a sensing period of the normal read operation is higher than a respective other one of the plurality of voltages applied during a sensing period of the verify read or erase operation.

The device may include a page buffer configured to receive respective ones of the plurality of voltages as control signals from the control circuit and supply corresponding voltages to the bit lines.

The plurality of voltages may include a first voltage and a second voltage, and the page buffer supplies a third voltage and a fourth voltage respectively based on the control signals at the first voltage and the second voltage to the bit line, wherein the first voltage and the third voltage are applied during the precharge period of a normal read operation, and the second voltage and the fourth voltage are applied during the precharge period of a verify read or erase operation, wherein the first voltage is greater than the second voltage, the third voltage and the fourth voltage, the second voltage is greater than the fourth voltage, and the third voltage is greater than the fourth voltage.

The page buffer may include a NMOS transistor having a threshold voltage, the first voltage and the third voltage differ by the threshold voltage, and the second voltage and the fourth voltage differ by the threshold voltage.

Each of a normal read operation and a verify read or erase operation may further include a develop period between the respective precharge and sensing periods, and when the non-volatile memory cell to which the bit line is connected is turned on, the voltage at the bit line drops from the third voltage to the fourth voltage.

The plurality of voltages may further include a fifth voltage and a sixth voltage, and the page buffer supplies a seventh voltage and an eighth voltage respectively based on the control signals at the fifth voltage and the sixth voltage to the bit line, wherein the fifth voltage and the seventh voltage are applied during the sensing period of a normal read operation, and the sixth voltage and the eighth voltage are applied during the sensing period of a verify read or erase operation, wherein the fifth voltage is greater than the sixth voltage, the seventh voltage and the eighth voltage, the sixth voltage is greater than the eighth voltage, and the seventh voltage is greater than the eighth voltage.

The page buffer may include a NMOS transistor having a threshold voltage, the fifth voltage and the seventh voltage differ by the threshold voltage, and the sixth voltage and the eighth voltage differ by the threshold voltage.

### BRIEF DESCRIPTION OF THE DRAWINGS

Features will become more apparent to those of ordinary skill in the art by describing in detail exemplary embodiments with reference to the attached drawings, in which:

FIG. 1 illustrates a block diagram of an exemplary embodiment of a non-volatile memory device;

FIG. 2 illustrates a schematic diagram of an exemplary embodiment of a circuit for providing a precharge voltage to a bit line of a memory cell array in the non-volatile memory device of FIG. 1;

FIGS. 3A and 3B illustrate timing diagrams of an exemplary normal read operation and an exemplary verify read operation or erase operation of the non-volatile memory device of FIG. 1;

FIG. 4 illustrates a flowchart of an exemplary embodiment of a method of controlling a precharge voltage of the non-volatile memory device of FIG. 1; and

FIG. 5 illustrates a block diagram of an exemplary embodiment of a memory system including the non-volatile memory device illustrated in FIG. 1.

### DETAILED DESCRIPTION

Exemplary embodiments now will be described more fully hereinafter with reference to the accompanying drawings, in which embodiments of the invention are shown. Features may, however, be embodied in many different forms and should not be construed as limited to the embodiments set forth herein. Rather, these embodiments are provided so that this disclosure will be thorough and complete, and will fully convey the scope of the inventive concept to those skilled in the art. In the drawings, the size and relative sizes of layers and regions may be exaggerated for clarity. Like numbers refer to like elements throughout the specification.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

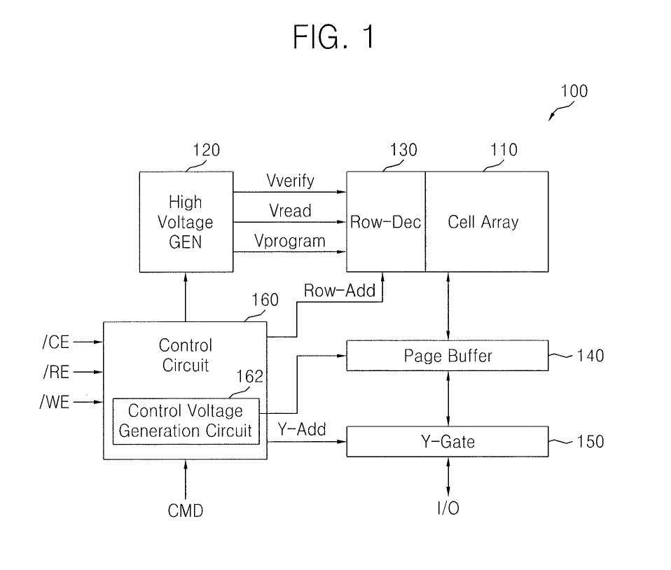

FIG. 1 illustrates a block diagram of an exemplary embodiment of a non-volatile memory device 100. The non-volatile memory device 100 may include a memory cell array 110, a high voltage generator 120, a row decoder 130, a page buffer 140, a Y-gating circuit 150, and a control circuit 160.

The memory cell array 110 may include a plurality of multi-level cells each of which may store a plurality of bits. Each of the multi-level cells may be connected to one of a plurality of bit lines and one of a plurality of word lines. Each multi-level cell may store data of at least two bits.

The high voltage generator 120 may generate word line voltages Vverify, Vread, and Vprogram, which may be provided (or applied) to the memory cell array 110. The high voltage generator 120 may generate different word line voltages for different operating modes and may provide the respective word lines voltages to a selected word line. During a program operation, the high voltage generator 120 may generate a program voltage Vprogram and may provide the program voltage Vprogram to a selected word line. During a read operation, the high voltage generator 120 may generate a read voltage Vread for data reading and may provide the read voltage Vread to a selected word line. During a verify operation, the high voltage generator 120 may generate a verify voltage Vverify for data verification and may provide the verify voltage Vverify to a selected word line.

The row decoder 130 may select a word line based on a row address Row-Add. The row decoder 130 may apply the word line voltage Vverify, Vread, or Vprogram generated by the high voltage generator 120 to the selected word line.

The page buffer 140 may operate as a sense amplifier or a write driver depending on an operating mode. More particularly, e.g., the page buffer 140 may operate as the write driver during a program operation to drive a bit line according to a bit to be stored in the memory cell array 110. The page buffer 140 may operate as the sense amplifier during a read operation to read the programmed bit from the memory cell array 110. The page buffer 140 may sense each of multiple bits stored in each of the multi-level cells.

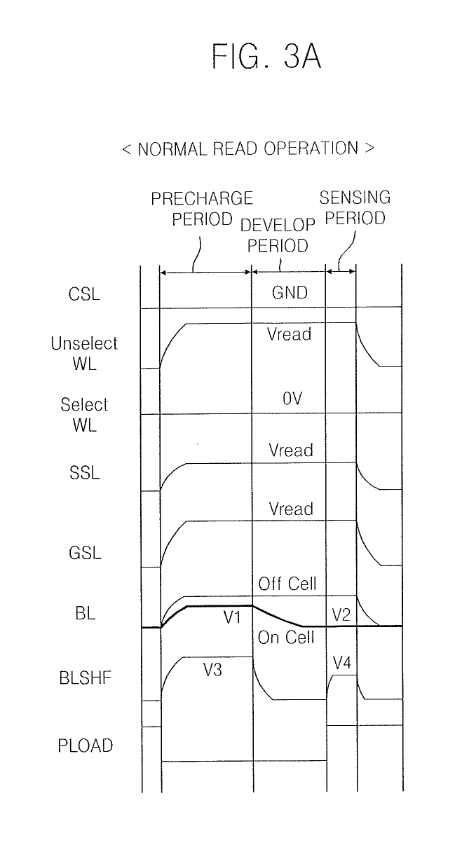

The page buffer 140 may be controlled by the control circuit 160 to apply a precharge voltage to a bit line connected to the memory cell array 110. During a normal read operation, the page buffer 140 may apply a precharge voltage of a second level V1 (FIG. 3A) to a bit line in response to a control signal BLSHF at a first level V3 during a precharge period. During a verify read or erase operation, the page buffer 140 may apply a precharge voltage of a fourth level V1′ to a bit line in response to the control signal BLSHF at a third level V3′.

The Y-gating circuit 150 may transmit data latched in the page buffer 140 to an input/output (I/O) buffer (not shown) in response to a column address Y-Add in a read operation. During a program operation, the Y-gating circuit 150 may transmit input data to the page buffer 140.

The control circuit 160 may control the high voltage generator 120 to generate voltages for program, verify, read and erase operations in response to externally input control signals. The control signal may be, e.g., a chip enable signal /CE, a read enable signal /RE, a write enable signal /WE, and a command signal CMD. The control circuit 160 may control the voltage of a control signal provided to a bit line during, e.g., a normal read operation, a verify read operation, or an erase operation. To control the voltage of the control signal, the control circuit 160 may further include a control voltage generation circuit 162.

During the normal read operation of the non-volatile memory device 100, the control voltage generation circuit 162 generates the control signal BLSHF at the first level V3 during a precharge period. When the control signal BLSHF at the first level V3 is provided to a bit line, the page buffer 140 provides a precharge voltage of the second level V1 to the bit line in response to the control signal BLSHF at the first level V3.

During the verify read or erase operation of the non-volatile memory device 100, the control voltage generation circuit 162 generates the control signal BLSHF at the third level V3′ during a precharge period. When the control signal BLSHF at the third level V3′ is provided to a bit line, the page buffer 140 provides a precharge voltage of the fourth level V1′ in response to the control signal BLSHF at the third level V3′.

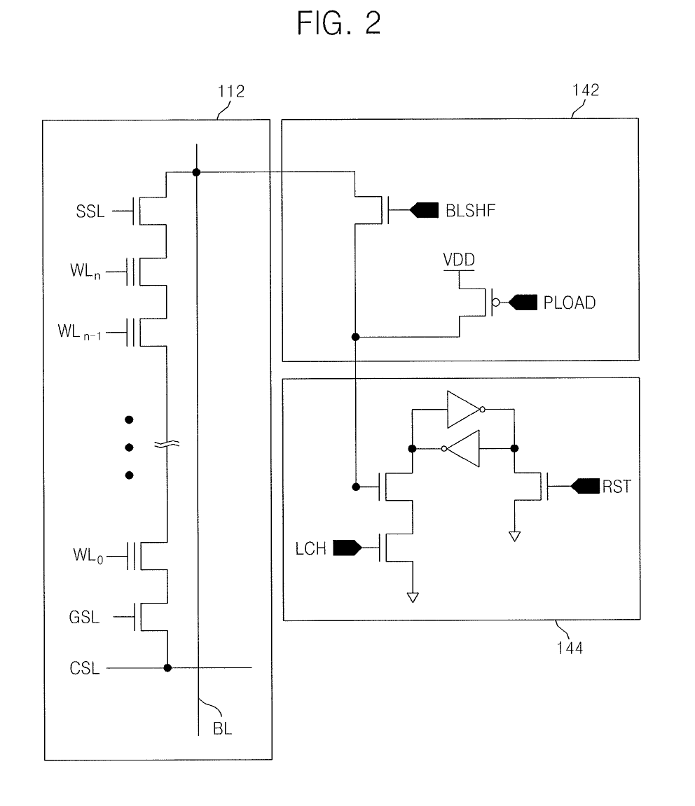

FIG. 2 illustrates a schematic diagram of an exemplary embodiment of a circuit for providing a precharge voltage to a bit line of a memory cell array in the non-volatile memory device 100 of FIG. 1. FIGS. 3A and 3B illustrate timing diagrams of an exemplary normal read operation and an exemplary verify read operation or erase operation of the non-volatile memory device 100 of FIG. 1.

Referring to FIGS. 1 and 2, a single bit line BL may be connected to a corresponding single string 112. The string 112 may be included in the cell array 100 of FIG. 1. The string 112 may include a string selection line SSL and a ground selection line GSL. In the string 112, a drain of a transistor connected to the string selection line SSL may be connected to the bit line BL and a source of a transistor connected to the ground selection line GSL may be connected to a common source line CSL. A plurality of transistors may be connected in series to each other between a source of the transistor connected to the string selection line SSL and a drain of the transistor connected to the ground selection line GSL. Gates of the respective transistors connected in series between the ground selection line GSL and the string selection line SSL may be respectively connected to word lines WL₀ through WLₙ.

The transistor connected to the string selection line SSL is controlled by a voltage applied through the string selection line SSL and the transistor connected to the ground selection line GSL is controlled by a voltage applied through the ground selection line GSL. The transistors connected between the ground selection line GSL and the string selection line SSL may be respectively controlled by voltages respectively applied through the word lines WL₀ through WLₙ and each of the transistors may store data as a single memory cell.

The string 112 may be connected with a precharge voltage control circuit 142. The precharge voltage control circuit 142 may include a P-type metal oxide semiconductor (PMOS) transistor controlled by a control signal PLOAD and an N-type metal oxide semiconductor (NMOS) transistor controlled by the control signal BLSHF. The PMOS transistor may be connected with a power supply voltage VDD and may receive the control signal PLOAD through its gate. The bit line BL may be precharged depending on the on/off state of the PMOS transistor. The NMOS transistor may be connected between the bit line BL and the PMOS transistor controlled by the control signal PLOAD and may receive the control signal BLSHF through its gate. The NMOS transistor receiving the control signal BLSHF electrically connects or disconnects the bit line BL and the PMOS transistor controlled by the control signal PLOAD. The precharge voltage control circuit 142 may be connected with a sensing and latch circuit 144. The sensing and latch circuit 144 senses a result of the normal/verify read operation during a sensing period. The precharge voltage generation circuit 142 and the sensing and latch circuit 144 may be included in the page buffer 140 of FIG. 1.

The voltage level of the bit line BL connected with the string 112 may be determined by the voltage level of the control signal BLSHF applied to the gate of the NMOS transistor and a threshold voltage Vth of the NMOS transistor. When a precharge voltage is applied to the gate of the NMOS transistor as the control signal BLSHF and the power supply voltage VDD is applied to a drain of the NMOS transistor, the bit line BL is precharged to a voltage level equal to the precharge voltage less the threshold voltage Vth.

Referring to FIGS. 1, 2, and 3A, during the precharge period of a normal read operation, when the bit line BL is precharged, a voltage of 0 V is applied to a selected word line “Select WL” and a read voltage Vread is applied to unselected word lines “Unselect WL”. The read voltage Vread is applied to the string selection line SSL and the ground selection line GSL and the control signal PLOAD is at a low level during the precharge period and until the end of a develop period. In addition, a voltage of the first level V3 generated by the control voltage generation circuit 162 is provided to the bit line BL as the control signal BLSHF and a voltage of the second level V1 is applied to the bit line BL in response to the control signal BLSHF at the first level V3. As a result, when a selected memory is an on-cell, the voltage level of the bit line BL decreases from the second level V1 to a sixth level V2. At this time, the threshold voltage Vth of the memory cell becomes lower than the voltage applied to the selected word line, and therefore, the memory cell is turned on. As a result, the NMOS transistor is turned on when the control signal BLSHF is applied to the bit line BL during the sensing period.

When the selected memory cell is an off-cell, the voltage level of the bit line BL is maintained at a high level during the develop period. At this time, since the threshold voltage Vth of the memory cell is higher than the voltage applied to the selected word line, the memory cell is turned off and current hardly flows in the memory cell. Accordingly, during the sensing period, the NMOS transistor is not turned on even though the control signal BLSHF is applied to the bit line BL.

Referring to FIGS. 1, 2, and 3B, during the precharge period of a verify read (or erase) operation, when the bit line BL is precharged, a voltage of 0 V is applied to all of the word lines WL₀ through WLₙ. The read voltage Vread is applied to the string selection line SSL and the ground selection line GSL and the control signal PLOAD is at a low level until the end of the develop period. In addition, a voltage of the third level V3′ generated by the control voltage generation circuit 162 is provided to the bit line BL as the control signal BLSHF and a voltage of the fourth level V1′ is applied to the bit line BL in response to the control signal BLSHF at the third level V3′. As a result, the bit line BL comes into an on-cell state and development is performed.

Here, the first level V3 is higher than or equal to the third level V3′. Accordingly, the second level V1 may be higher than or equal to the fourth level V1′.

During the sensing period of the normal read operation of the non-volatile memory device 100, the a voltage of a fifth level V4 generated by the control voltage generation circuit 162 is applied as the control signal BLSHF and a voltage of a sixth level V2 is applied to the BL is applied to the bit line BL in response to the control signal BLSHF at the fifth level V4.

During the sensing period of the verify read (or erase) operation, a voltage of a seventh level V4′ generated by the control voltage generation circuit 162 is applied as the control signal BLSHF and a voltage of an eighth level V2′ is applied to the bit line BL in response to the control signal BLSHF at the seventh level V4′.

Here, the fifth level V4 may be higher than or equal to the seventh level V4′. Accordingly, the sixth level V2 may be higher than or equal to the eighth level V2′.

When the precharge voltage applied to the bit line BL during the normal read operation is different from the precharge voltage applied to the bit line BL during the verify read (or erase) operation as described above, a failure rate is decreased as compared to a case where the same precharge voltage is applied to the bit line BL during both the normal read operation and the verify read operation. In other words, when a precharge voltage to the bit line BL is different between the normal read operation and the verify read or erase operation, the non-volatile memory device 100 decreases the failure rate of memory cells and the average number of erase loops, thereby preventing and/or reducing degradation of cycle endurance due to excessive erases.

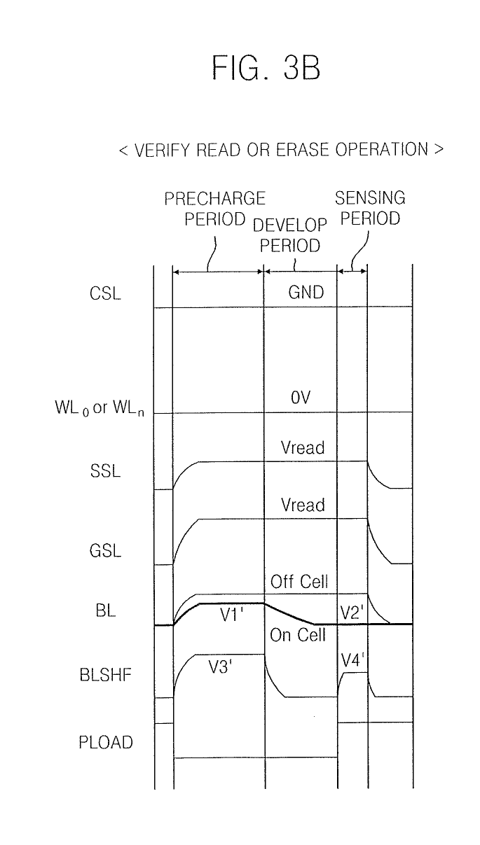

FIG. 4 illustrates a flowchart of an exemplary embodiment of a method of controlling a precharge voltage of the non-volatile memory device 100 of FIG. 1.

Referring to FIGS. 1, 3, and 4, the page buffer 140 of the non-volatile memory device 100 may apply a precharge voltage of the second level V1 to the bit line BL in response to the control signal BLSHF at the first level V3 during a precharge period so that a normal read operation is performed (S210). Thereafter, the page buffer 140 of the non-volatile memory device 100 applies a precharge voltage of the fourth level V1′ to the bit line BL in response to the control signal BLSHF at the third level V3′ during a precharge period so that a verify read or erase operation is performed (S220).

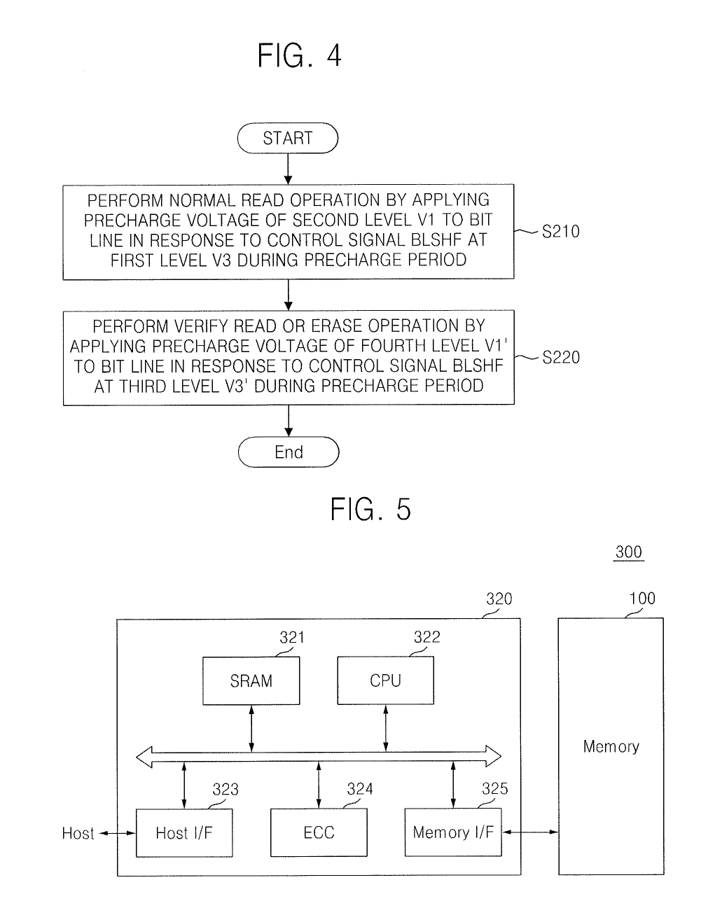

FIG. 5 illustrates a block diagram of an exemplary embodiment of a memory system including the non-volatile memory device 100 illustrated in FIG. 1.

Referring to FIGS. 1 and 5, the memory system 300 may support a large data storage capacity. The memory system 300 may include the non-volatile memory device 100 and a memory controller 320.

The memory controller 320 may control data exchange between a host and the non-volatile memory device 100. The memory controller 320 includes a static random access memory (SRAM) 321, a processor 322, a host interface 323, an error correction circuit 324, and a memory interface 325.

The SRAM 321 is used as an operation memory for the processor 322. The processor 322 may control data exchange of the memory controller 320. The host interface 323 may include a data exchange protocol of the host connected with the memory system 300. The error correction circuit 324 may perform error detection and error correction on a plurality of hard decision data bits using soft decision data output from the non-volatile memory device 100. The memory interface 325 may interface with the non-volatile memory device 100.

The memory system 300 may be implemented by a solid state drive (SSD). In this case, burden on the error correction circuit 324 can be significantly reduced. In addition, the memory system 300 may be combined, e.g., with an application chipset, a camera image processor, or a mobile dynamic random access memory (DRAM) to be provided as a storage device for information processing equipment that can exchange a large amount of data.

In one or more embodiments, memory cells may be implemented using one of various cell structures having a charge storage layer. A cell structure having a charge storage layer may be a charge trap flash structure using a charge trapping layer, a stack flash structure in which plural arrays are stacked, a flash structure without source and drain, or a pin-type flash structure.

In one or more embodiments, a precharge voltage applied to a bit line connected with a non-volatile memory cell is controlled so that program/erase endurance is increased.

Exemplary embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope of the inventive concept as set forth in the following claims.

What is claimed is:

1. A non-volatile memory device, comprising:
a bit line connected with a non-volatile memory cell;
a precharge voltage generation circuit configured to generate a precharge voltage during a precharge operation; and
a control circuit configured to apply the precharge voltage of a second level to the bit line in response to a control signal at a first level during a precharge period during a normal read operation and to apply the precharge voltage of a fourth level to the bit line in response to the control signal at a third level during a precharge period during a verify read operation or erase operation.

2. The non-volatile memory device as claimed in claim 1, wherein the first level is higher than the third level and the second level is higher than the fourth level.

3. The non-volatile memory device as claimed in claim 1, further comprising a control voltage generation circuit configured to generate the control signal.

4. The non-volatile memory device as claimed in claim 3, wherein the control voltage generation circuit is configured to generate the control signal at a fifth level during a sensing period during the normal read operation and generate the control signal at a sixth level lower than the fifth level during a sensing period during the verify read or erase operation.

5. A memory system, comprising:
the non-volatile memory device as claimed in claim 1; and
a memory controller configured to control the non-volatile memory device.

6. The memory system as claimed in claim 5, wherein the first level is higher than the third level and the second level is higher than the fourth level.

7. The memory system as claimed in claim 5, wherein the non-volatile memory device further includes a control voltage generation circuit configured to generate the control signal.

8. The memory system as claimed in claim 7, wherein the control voltage generation circuit is configured to generate the control signal at a fifth level during a sensing period during the normal read operation and generate the control signal at a sixth level lower than the fifth level during a sensing period during the verify read or erase operation.

9. A method of controlling a precharge voltage in a non-volatile memory device, the method comprising:
applying the precharge voltage of a second level to a bit line in response to a control signal at a first level during a precharge period during a normal read operation; and
applying the precharge voltage of a fourth level to the bit line in response to the control signal at a third level during a precharge period during a verify read or erase operation.

10. The method as claimed in claim 9, wherein the first level is higher than the third level and the second level is higher than the fourth level.

11. The method as claimed in claim 9, further comprising:
generating the control signal at a fifth level during a sensing period during the normal read operation; and
generating the control signal at a sixth level lower than the fifth level during a sensing period during the verify read or erase operation.

12. A non-volatile memory device including a plurality of non-volatile memory cells, comprising:
a bit line connected to at least one the plurality of non-volatile memory cells configured to be controlled during a normal read operation and a verify read or erase operation, each of the normal read operation and the verify read or erase operation including a plurality of periods; and
a control circuit configured to apply a plurality of voltages having different magnitudes to the bit line, wherein at least one of the plurality of voltages applied during one of the plurality of periods of the normal read operation is higher than another of the plurality of voltages applied during a same respective one of the plurality of periods of the verify read or erase operation.

13. The non-volatile memory device as claimed in claim 12, wherein the plurality of periods include a precharge period and the respective one of the plurality of voltages applied during a precharge period of the normal read operation is higher than a respective other one of the plurality of voltages applied during a precharge period of the verify read or erase operation.

14. The non-volatile memory device as claimed in claim 13, wherein the plurality of periods include a sensing period and the respective one of the plurality of voltages applied during a sensing period of the normal read operation is higher than a respective other one of the plurality of voltages applied during a sensing period of the verify read or erase operation.

15. The non-volatile memory device as claimed in claim 14, further including a page buffer configured to receive respective ones of the plurality of voltages as control signals from the control circuit and supply corresponding voltages to the bit lines.

16. The non-volatile memory device as claimed in claim 15, wherein the plurality of voltages include a first voltage and a second voltage, and the page buffer supplies a third voltage and a fourth voltage respectively based on the control signals at the first voltage and the second voltage to the bit line, wherein the first voltage and the third voltage are applied during the precharge period of a normal read operation, and the second voltage and the fourth voltage are applied during the precharge period of a verify read or erase operation, wherein the first voltage is greater than the second voltage, the third voltage and the fourth voltage, the second voltage is greater than the fourth voltage, and the third voltage is greater than the fourth voltage.

17. The non-volatile memory device as claimed in claim 16, wherein the page buffer includes a NMOS transistor having a threshold voltage, the first voltage and the third voltage differ by the threshold voltage, and the second voltage and the fourth voltage differ by the threshold voltage.

18. The non-volatile memory device as claimed in claim 17, wherein the at least one non-volatile memory cell includes a charge storage layer.

19. The non-volatile memory device as claimed in claim 16, wherein the plurality of voltages further include a fifth voltage and a sixth voltage, and the page buffer supplies a seventh voltage and an eighth voltage respectively based on the control signals at the fifth voltage and the sixth voltage to the bit line, wherein the fifth voltage and the seventh voltage are applied during the sensing period of a normal read operation, and the sixth voltage and the eighth voltage are applied during the sensing period of a verify read or erase operation, wherein the fifth voltage is greater than the sixth voltage, the seventh voltage and the eighth voltage, the sixth voltage is greater than the eighth voltage, and the seventh voltage is greater than the eighth voltage.

20. The non-volatile memory device as claimed in claim 19, wherein the page buffer includes a NMOS transistor having a threshold voltage, the fifth voltage and the seventh voltage differ by the threshold voltage, and the sixth voltage and the eighth voltage differ by the threshold voltage.
